(19) United States
(12) Patent Application Publication
(10) Pub. No.: US 2006/0288928 A1
(43) Pub. Date: Dec. 28, 2006

(54) Perovskite-based thin film structures on miscut semiconductor substrates

(76) Inventors: Chang-Beom Eom, Madison, WI (US); Darrell Galen Schlom, State College, PA (US)

Correspondence Address: FOLEY & LARDNER LLP, 150 EAST GILMAN STREET, P.O. BOX 1497, MADISON, WI, 53701-1497, US

(21) Appl. No.: 11/149,951

(22) Filed: Jun. 10, 2005

(51) Int. Cl. B32B 9/00; B32B 19/00; B32B 13/04; C30B 23/00; C30B 28/14; C30B 25/00; C30B 28/12

(52) U.S. Cl. 117/89; 117/84

(57) ABSTRACT

A perovskite-based thin film structure includes a semiconductor substrate layer, such as a crystalline silicon layer, having a top surface cut at an angle to the (001) crystal plane of the crystalline silicon. A perovskite seed layer is epitaxially grown on the top surface of the substrate layer. An overlayer of perovskite material is epitaxially grown above the seed layer. In some embodiments the perovskite overlayer is a piezoelectric layer grown to a thickness of at least 0.5 μm and having a substantially pure perovskite crystal structure, preferably substantially free of pyrochlore phase, resulting in large improvements in piezoelectric characteristics as compared to conventional thin film piezoelectric materials.

### STATEMENT OF GOVERNMENT RIGHTS

This invention was supported by the National Science Foundation (NSF) under grant numbers 0296021 and 0313764. The United States federal government has certain rights in this invention.

### FIELD OF THE INVENTION

This invention pertains generally to the field of semiconductor and related device manufacturing and particularly to perovskite-based thin film structures.

### BACKGROUND OF THE INVENTION

Most microelectromechanical systems (MEMS) are based on silicon or other semiconductors. It is desirable to be able to incorporate mechanical actuators and sensors with the MEMS semiconductor substrate in a manner which is compatible with processing of semiconductor substrates to form microelectronics or other devices. Piezoelectric materials have been incorporated on substrates with MEMS devices to form various types of actuators, positioners, drivers, and sensing elements. Typically, this has been accomplished by producing piezoelectric elements from bulk crystalline piezoelectric material and then adhering or otherwise attaching the piezoelectric element to the MEMS substrate. To reduce fabrication costs and to allow formation of smaller and more integrated devices, it would be desirable to be able to form thin films of piezoelectric material directly on the semiconductor substrate using processes which are compatible with other semiconductor processing. However, piezoelectric crystalline materials grown on semiconductor substrates such as silicon often have significantly reduced piezoelectric qualities as compared to bulk crystals of the piezoelectric material.

Examples of piezoelectric materials with desirable properties for MEMS applications include Pb(Mg_{1/3}Nb_{2/3})O₃—PbTiO₃ (PMN-PT), Pb(Zn_{1/3}Nb_{2/3})O₃—PbTiO₃ (PZN-PT), and Pb(Zr_{0.52}Ti_{0.48})O₃ (PZT). Single crystals of these materials exhibit a giant piezoelectric response. Such lead-based relaxor-ferroelectric solid solutions have extremely large values of piezoelectric coefficients along the non-polar <001> pseudocubic directions of the rhombohedral phase, and are utilized in bulk actuation and sensor devices. It would be very desirable to be able to achieve similar piezoelectric properties in thin films integrated with silicon. For this to be accomplished, however, it is necessary to deposit high-quality films to thicknesses greater than 1 μm with excellent control over crystallographic orientation. In relaxor-ferroelectric crystals the physical properties are maximal at or near the morphotropic phase boundary (MPB), which occurs at 33% PT in the PMN-PT solid solution system. Unfortunately, the epitaxial PMN-PT films reported so far have much lower values of longitudinal piezoelectric coefficients (d₃₃) (e.g., 250 pm/V) than bulk single crystals of the material (>2000 pm/V). D. Lavric, et al., “Epitaxial Thin Film Heterostructures of Relaxor Ferroelectric Pb(Mg_{1/3}Nb_{2/3})O₃—PbTiO₃,” Integr. Ferroelectri., Vol. 21, 1998, pp. 499-509; J. P. Maria, et al., “Phase Development and Electrical Property Analysis of Pulsed Laser Deposited Pb(Mg_{1/3}Nb_{2/3})O₃—PbTiO₃, (70/30) Epitaxial Thin Films,” J. Appl. Phys., Vol. 84, 1998, pp. 5147-5154; V. Nagaraj an, et al., “Role of Substrate on the Dielectric and Piezoelectric Behavior of Epitaxial Lead Magnesium Niobate-Lead Titanate Relaxor Thin Films,” Appl. Phys. Lett., Vol. 77, 2000, pp. 438-440; J. H. Park, et al., “Dielectric and Piezoelectric Properties of Sol-gel Derived Lead Magnesium Niobium Titanate Films with Different Textures,” J. Appl. Phys., Vol. 89, 2001, pp. 568-574. One contributor to this difference is that a non-piezoelectric pyrochlore phase often dominates at the larger film thicknesses (>1 μm) that are of most interest for piezoelectric applications, with a consequent significant reduction in piezoelectric response.

### SUMMARY OF THE INVENTION

In accordance with the present invention, a perovskite-based thin film structure is formed on a miscut semiconductor substrate, such as silicon. In some embodiments, the structures incorporate a piezoelectric perovskite layer grown over the miscut silicon using a seed layer. In some such embodiments, the piezoelectric characteristics of the perovskite are comparable to those of the bulk piezoelectric material.

A thin film structure in accordance with the invention includes a semiconductor substrate layer such as crystalline silicon having a top surface cut at an angle to the (001) crystal plane of the crystalline silicon, with the angle of cut being between 1° and 20°. Most preferably, the angle of cut is 4° or about 4° (e.g., 3-5°) to the (001) plane of the crystalline substrate toward the (110) plane. A perovskite seed layer is epitaxially grown on the top surface of the substrate layer.

The perovskite seed layer may be any perovskite having the formula ABO₃ or any perovskite-related compound containing ABO₃ subunits, upon which an epitaxial layer of the piezoelectric material may be grown. In the formula, A is an element selected from Group IA, IB, IIA, IIIB, IIIA, IIIB, IVA, or VA of the periodic table and B is an element selected from Group IA, IB, IIA, 111B, IIIA, IIB, IVA, IVB, VA, VB, VIB, VIIA, VIIB, or VIIIB of the periodic table. Titanates, including barium, calcium, lead and strontium titanates are particularly well-suited for this application. Other suitable perovskites include, but are not limited to, LaAlO₃, DyScO₃, GdScO₃, LaScO₃, CaTiO₃, BaTiO₃, PbTiO₃, CaZro₃, SrZrO₃, BaZro₃, SrHfO₃, PbZrO₃, KNbO₃, and KTaO₃. Solid solutions, i.e., mixtures such as (La,Sr)MnO₃ or (Pb,La)TiO₃, of perovskites or doped perovskites (e.g., La-doped SrTiO₃) are also suitable. Examples of other suitable perovskites may be found in Hellwege, et al., Landolt-Börnstein: Numerical Data and Functional Relationships in Science and Technology, Group III, Vol. 12a (Springer-Verlag, Berlin, 1978), pp. 126-206, and Galasso, Francis S., Perovskites and High Tc Superconductors (New York, Gordon and Breach Science Publishers, cb 1990), which are incorporated herein by reference. Typical perovskite seed layer materials include SrTiO₃, doped SrTiO₃ and SrRuO₃, as well as other perovskite materials. SrTiO₃ is a particularly suitable perovskite seed layer material due to its lattice match with PMN-PT and its relatively low growth temperature.

An overlayer of perovskite is epitaxially grown above the seed layer, desirably to a thickness of at least 0.1 μm. This includes embodiments where the overlayer is grown to a thickness of at least about 0.2 μm and further includes embodiments where the overlayer is grown to a thickness of at least about 0.5 μm. As used herein the term “overlayer” simply refers to a layer of perovskite material that is disposed above the perovskite seed layer, although additional layers, such as electrode layers, may be interposed between the seed layer and the overlayer. This overlayer desirably has a substantially pure perovskite crystal structure. If the overlayer is composed of a piezoelectric perovskite, the preferred piezoelectric thin film structures in accordance with the invention are grown to be substantially free of pyrochlore phase, resulting in large improvements in piezoelectric characteristics as compared to conventional thin film piezoelectric materials.

The perovskite overlayer may be composed of a variety of perovskites, including those listed above for the seed layer. Examples of overlayer perovskites include piezoelectric perovskites, such as PMN-PT, PZN-PT, PZT, and BaTiO₃; ferroelectric perovskites; magnetic perovskites, such as SrRuO₃ and the ferrites NiFe₂O₄, CoFe₂O₄, LaMnO₃ and SrMnO₃; pyroelectric perovskites; non-liner optical perovskites, such as LiNbO₃, BaTiO₃ and LiTaO₃; multiferroic perovskites, such as BiFeO₃; and superconducting perovskites, such as YBa₂Cu₃O₇. As one of skill in the art would recognize, some perovskites will fall into more that one of the above-listed categories. Depending on the nature of the perovskite overlayer, the structures may be used in a range of devices including, but not limited to, the use of ferroelectric perovskite-based structures in memory applications; the use of pyroelectric-based structures in thermal sensing applications; the use of piezoelectric perovskite-based structures in piezoelectric devices; the use of non-linear optical perovskite-based structures in optical modulators; the use of multiferroic perovskite-based structures in sensing, memory and spintronic devices; and the use of superconducting perovskite-based structures in current limiters and coated conductors.

A particularly preferred piezoelectric material for use in the invention is PMN-PT. PMN-PT is a solid solution of PMN and the perovskite PbTiO₃ (PT). PMN-PT actually encompasses a range of compositions defined by the PT content of the material. In some embodiments of the invention, the mole percent of PT in the compositions may be between 1 and 99 percent. In some preferred embodiments, the composition is near the morphotropic phase boundary of the PMN-PT, having a PT content of between about 5 and 40%, preferably between 30 and 38%. Similarly, PZN-PT is a solid solution of PZN and PT. PZN-PT actually encompasses a range of compositions defined by the PT content of the material. In some embodiments of the invention, the mole percent of PT in the compositions may be between 1 and 99 percent. In some preferred embodiments, the composition is near the morphotropic phase boundary of the PZN-PT, having a PT content of between about 1 and 20%, preferably between 3 and 11%.

Some ofthe present structures include a first perovskite overlayer disposed over the perovskite seed layer, a second perovskite overlayer disposed over the first perovskite overlayer and, optionally, a third perovskite overlayer disposed over. the second perovskite overlayer. In one such embodiment, the second perovskite overlayer is composed of a piezoelectric material and the first and third perovskite overlayers provide electrodes sandwiching the piezoelectric perovskite overlayer. However, electrodes other than perovskite-based electrodes may also be used. Examples of perovskites that may be used to make the electrodes include SrRuO₃ and CaRuO₃. SrRuO₃ is a preferred electrode material for use with PMN-PT-based structures due to its small lattice mismatch with PMN-PT (33%), which allows the growth of high quality epitaxial heterostructures with SrRuO₃ electrodes. In addition, SrRuO₃ is stable up to 1200K in oxidizing or inert gas environments and shows good metallic behavior, which is important for electrode applications. The fully formed thin film structure with top and bottom electrode layers may be cut to provide separate capacitor structures in which the electrode layers are separated by the piezoelectric layer.

In a preferred embodiment, the perovskite-based thin film structures are stacked structures that include two or more electrodes sandwiched between sequentially stacked piezoelectric layers. In addition to allowing for parallel electrical wiring, such stacked structures allow the stacks to be driven at higher electric fields, thus taking advantage of the high saturation strain without increasing driving voltages. These characteristics make the structures particularly well suited for use in MEMS, such as miniature devices, high frequency ultrasound transducer assays, tunable dielectrics, and capacitors.

Further objects, features and advantages of the invention will be apparent from the following detailed description when taken in conjunction with the accompanying drawings.

### BRIEF DESCRIPTION OF THE DRAWINGS

In the drawings:

FIG. 1 is a simplified cross-sectional view of a perovskite-based thin film structure in accordance with the invention.

FIG. 2 shows X-ray θ-2θ diffraction spectra of epitaxial PMN-PT (3.5 μm thick) grown on a SrRuO₃ thin film grown on a SrTiO₃-buffered vicinal (001) silicon substrate and on a bulk SrTiO₃ substrate.

FIG. 3 shows a φ-scan of the 202 PMN-PT reflection for the PMN-PT on vicinal Si, wherein the full width half maximum (FWHM) of the 002 PMN-PT peak is 0.3° in 2θ and 0.26° in ω (rocking curve).

FIG. 4 shows a comparison of the in-plane and out-of-plane lattice parameters of the PMN-PT films grown on SrTiO₃ and SrTiO3/vicinal Si, illustrating the different stress states experienced by the films on the two substrates. As a reference, the pseudocubic lattice parameter of PMN-PT of a similar composition is also given.

FIG. 5 is a bright-field cross-sectional TEM image of a 3.5 μm thick PMN-PT/SrRuO₃ thin film grown on SrTiO₃-buffered vicinal Si.

FIG. 6 is an SAED (selected area electron diffraction) pattern from the SrTiO₃ layer (viewed along the [010] SrTiO₃ zone axis) and the underlying vicinal (001) silicon substrate (viewed along the [110] Si zone axis) in the 3.5 μm thick PMN-PT/SrRuO₃ thin film grown on SrTiO₃-buffered vicinal Si.

FIG. 7 is an SAED pattern from the SrRuO₃ layer (viewed along the [010] zone axis of SrRuO₃) in the 3.5 μm thick PMN-PT/SrRuO₃ thin film grown on SrTiO₃-buffered vicinal Si. Note that pseudocubic indices are used for SrRuO₃ throughout this patent unless otherwise specified. SrRuO₃ is truly orthorhombic and the SAED pattern is viewed simultaneously along both the [110]_{orthorhombic} and [001]_{orthorhombic} zone axes of SrRuO₃ using orthorhombic indices, because the SrRuO₃ film is twinned. With pseudocubic indices these zone axes are both equivalent to [010].

FIG. 8 is an SAED pattern from the PMN-PT layer (viewed along the [010] PMN-PT zone axis) in the 3.5 μm thick PMN-PT/SrRuO₃ thin film grown on SrTiO₃-buffered vicinal Si.

FIG. 9 are graphs of polarization vs. electric field of 3.5 μm thick PMN-PT films for both continuous and nanostructured film capacitors grown on SrTiO₃-buffered vicinal Si.

FIG. 10 are graphs of polarization vs. electric field for 3.5 μm thick PMN-PT film for a continuous capacitor on SrTiO₃.

FIG. 11 are graphs of d₃₃ vs. electric field for a 3.5 μm thick PMN-PT film for continuous and separated capacitors on SrTiO₃-buffered vicinal Si.

FIG. 12 are graphs of d₃₃ vs. electric field for a 3.5 μm thick PMN-PT film for continuous and separated capacitors on SrTiO₃.

### DETAILED DESCRIPTION OF THE INVENTION

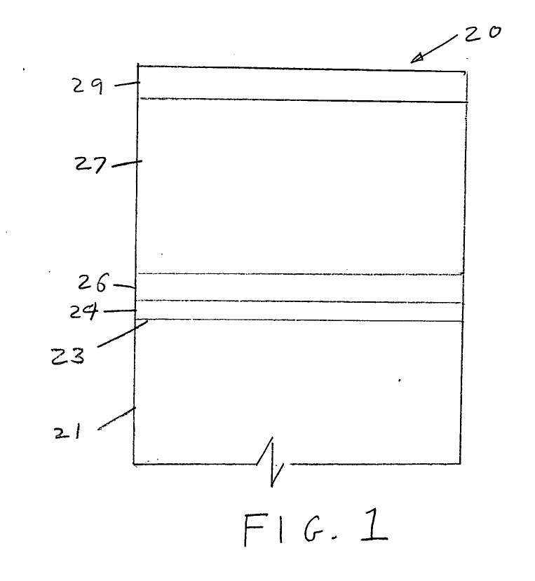

For purposes of illustrating the invention, a simplified cross-section of a perovskite-based thin film structure is shown generally at 20 in FIG. 1. The structure 20 has a semiconductor substrate layer 21 with a top surface 23. A perovskite seed layer 24 is epitaxially grown on the top surface 23, a first perovskite overlayer 26, serving as a bottom electrode, may be formed on the seed layer 24, and preferably is epitaxially grown thereon. A second perovskite overlayer 27 (e.g., a piezoelectric layer) is deposited on the bottom electrode 26, and a third perovskite overlayer 29, serving as a top electrode, is preferably deposited on the second perovskite overlayer 27. As discussed further below, the top surface 23 of the crystalline semiconductor substrate 21 is cut at an angle to a crystal plane of the substrate crystal structure.

The following illustrative embodiments are intended to further exemplify the perovskite-based thin film structures. These embodiments should not be interpreted as limiting the scope of the structures disclosed herein.

### EXAMPLES

### Example 1

### Fabrication of a PMN-PT-Based Piezoelectric Thin Film Structure

An example of a preferred substrate 21 that may be utilized in the invention is a (001) Si wafer coated with a seed layer 24 of SrTiO₃. The epitaxial SrTiO₃ layer 24 may be deposited by reactive molecular beam epitaxy (MBE) or other suitable processes. A suitable process is described in J. Lettieri, “Critical Issues of Complex, Epitaxial Oxide Growth and Integration with Silicon by Molecular Beam Epitaxy,” Ph.D. Thesis (Pennsylvania State University, 2002), available on-line at http://etda.libraries.psu.edu/theses/approved/WorldWidelndex/ETD-202/index.html. The top surface 23 of the (001) Si wafer 21 is preferably miscut by 1° to 20°, most preferably 4°, toward (110) to improve the epitaxy of PMN-PT thick films and suppress pyrochlore phase formation. A 100 nm thick conducting SrRuO₃ bottom electrode 26 is then deposited at a substrate temperature of 600° C. by 90° off-axis radio-frequency (RF) magnetron sputtering from a stoichiometric sintered target or other suitable processes. SrRuO₃is an ideal bottom electrode for epitaxial piezoelectric heterostructures since it is a conductive perovskite with a reasonable lattice match with PMN-PT. A 1-4 μm thick (Pb(Mg_{1/3}Nb_{2/3})O₃)_{0.67}—(PbTiO₃)_{0.33} (PMN-PT) film 27 is then deposited by on-axis RF-magnetron sputtering from a target with composition (Pb(Mg_{1.23/3}Nb_{1.73/3})O₃)_{0.67}—(PbTiO₃)_{0.33}+PbO (5 mol % excess) or other suitable processes. During PMN-PT film deposition, the substrate temperature is maintained at 670° C. with argon and oxygen partial pressures of 240 mTorr and 160 mTorr, respectively. Chemical composition measurements by wavelength dispersive spectroscopy (WDS) show that the SrRuO₃ and PMN-PT films are stoichiometric within experimental error. A 50 nm thick SrRuO₃ top electrode 29 is then deposited by pulsed-laser deposition (PLD) or other suitable processes. To relieve the effects of substrate-induced constraint on the piezo-response, the multilayer films 26, 27, 29 can be patterned by focused ion beam (FIB) milling down to the bottom electrode, thus yielding capacitors with lateral dimensions in the 0.5-3 μm range and allowing access to the bottom electrode 24 for electrical connections.

The phase purity, crystal structure, and epitaxial arrangements were studied using a four-circle x-ray diffractometer with both a two-dimensional area detector and a four-bounce monochromator. The θ-2θ scans in FIG. 2 show the strong 00l peaks from the perovskite PMN-PT phase in 3.5 μm thick films grown on 4° miscut (001) Si and SrTiO₃ substrates. Films as thick as 3.5 μm on miscut Si substrates were nearly phase-pure pure perovskite PMN-PT. In contrast, PMN-PT films on well-oriented (+0.1) (001) Si are found to contain a high volume fraction of pyrochlore phases.

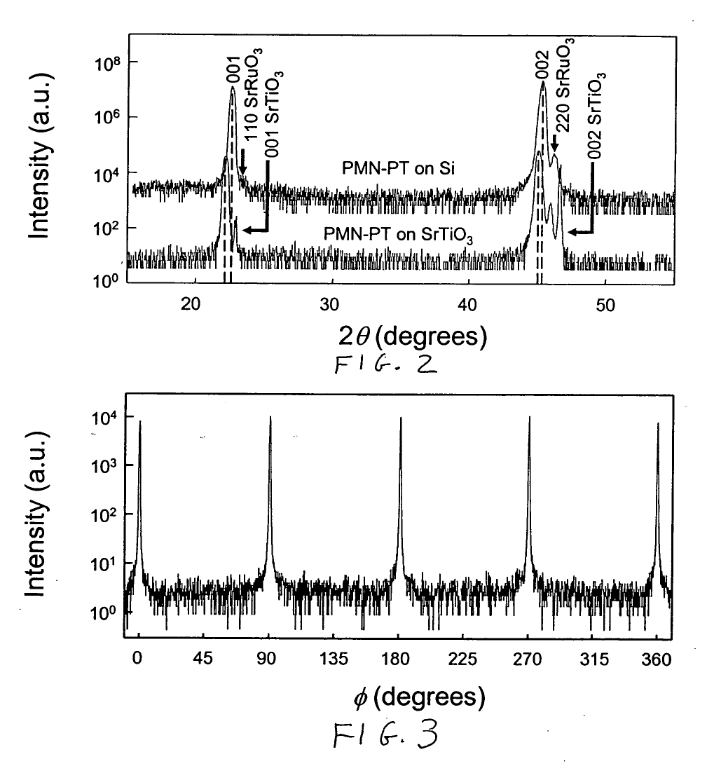

This behavior may be attributed to the variation in terrace length with miscut angle. As the miscut angle increases, so does the concentration of ledge and kink sites on the surface. Volatile species, such as lead in the case of PMN-PT, are expected to be more tightly bound at ledge and kink sites than atop a terrace. Thus, the role of substrate miscut may be to maintain film stoichiometry by decreasing the propensity for volatile species to desorb. Pyrochlore phases were observed in PMN-PT films thicker than 4 μm, even on 4° miscut (001) Si. The full width at half maximum (FWHM) of the rocking curve for the PMN-PT 002 reflection is 0.26° for the 3.5 μm thick film, which confirms the high crystalline quality of the films. As expected, azimuthal ø scans in FIG. 3 show in-plane epitaxy with a cube-on-cube epitaxial relationship, [100] PMN-PT/[100] SrRuO₃//[100] SrTiO₃//[110]Si.

FIG. 4 compares the out-of-plane and in-plane lattice parameters of the 3.5 μm thick films grown on Si and bulk SrTiO₃ substrates. We find that the film on Si is under biaxial tension due to the thermal expansion mismatch of PMN-PT with Si. This PMN-PT film has in-plane lattice parameters of 4.027±0.002 Å and an out-of-plane lattice parameter of 3.998±0.002 Å. For comparison, the pseudocubic bulk lattice parameter of PMN-PT is 4.02 Å. On the other hand, the PMN-PT films grown on bulk SrTiO₃ show the opposite behavior. The X-ray diffraction results in FIG. 2 indicate a clear peak shift towards lower angles (or bigger out-of-plane lattice parameters) for the film on bulk SrTiO₃ compared to Si, with an out-of-plane lattice parameter of 4.032±0.001 Å and in-plane lattice parameter of 4.000±0.003 Å. The impact of this remanent stress on the ferroelectric and piezoelectric properties is described below.

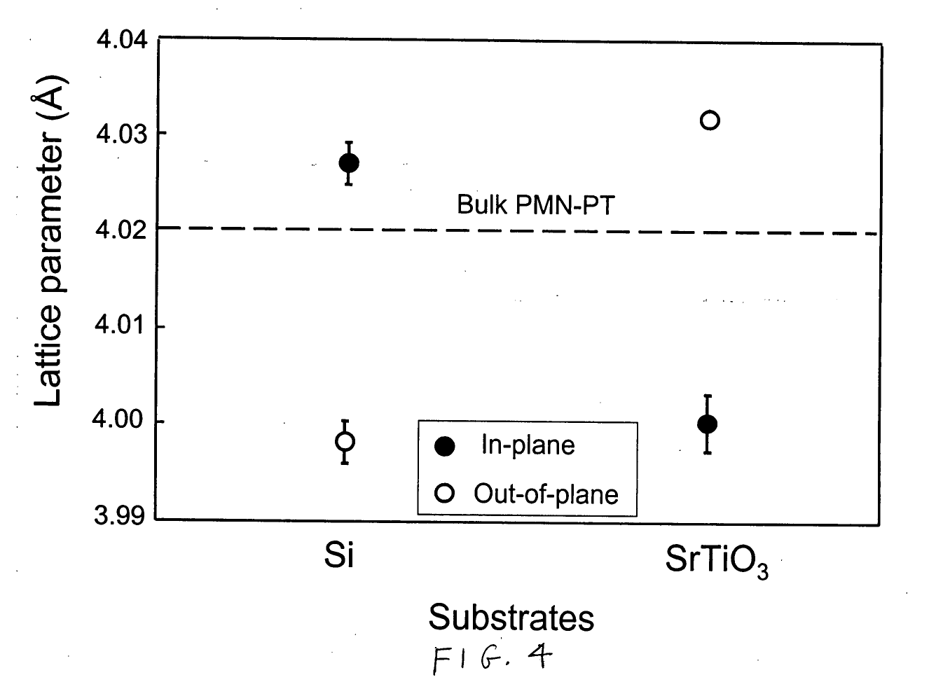

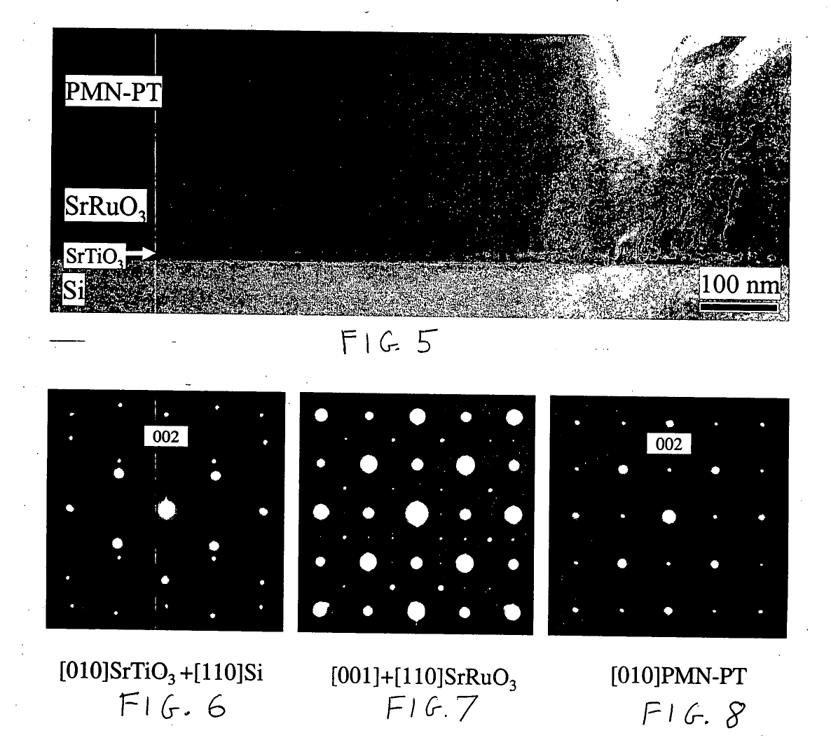

Transmission electron microscopy (TEM) was used to confirm epitaxial growth of the PMN-PT on Si. FIG. 5 is a low magnification bright-field TEM image of a 3.5 μm thick PMN-PT/SrRuO₃/SrTiO₃/Si heterostructure. FIGS. 6, 7, and 8 are the selected-area electron diffraction (SAED) patterns taken from the SrTiO₃ (as well as the underlying Si substrate), SrRuO₃, and PMN-PT layers in this heterostructure, respectively. They are, respectively, identified as the superimposition of the [010] zone axis diffraction pattern of SrTiO₃ and the [110] zone axis diffraction pattern of Si, the superimposition of the [001]_{orthorhombic} zone axis and [110]_{orthorhombic} zone axis diffraction patterns of SrRuO₃, and the [010] zone axis diffraction pattern of PMN-PT. The epitaxial growth of PMN-PT is evident. No pyrochlore phase is observed in the 3.5 μm thick PMN-PT film grown on a 4° miscut (001) Si substrate. A high density of antiphase boundaries are observed in the PMN-PT film on miscut Si substrates, which originate from the atomic steps on the Si substrates. In contrast, PMN-PT films grown on precisely oriented (001) Si substrates with otherwise identical growth conditions show fewer antiphase boundaries.

In situ TEM experiments using both heating and cooling stages reveal that the PMN-PT film grown on a SrTiO₃ substrate contains ferroelectric domains until 373 K upon heating, while the domain structure is not observed until cooling to ˜200 K for a similar film grown on a vicinal (001) Si substrate. This indicates that the PMN-PT film on SrTiO₃ may consist of a normal ferroelectric phase, whereas the film on Si remains a relaxor ferroelectric.

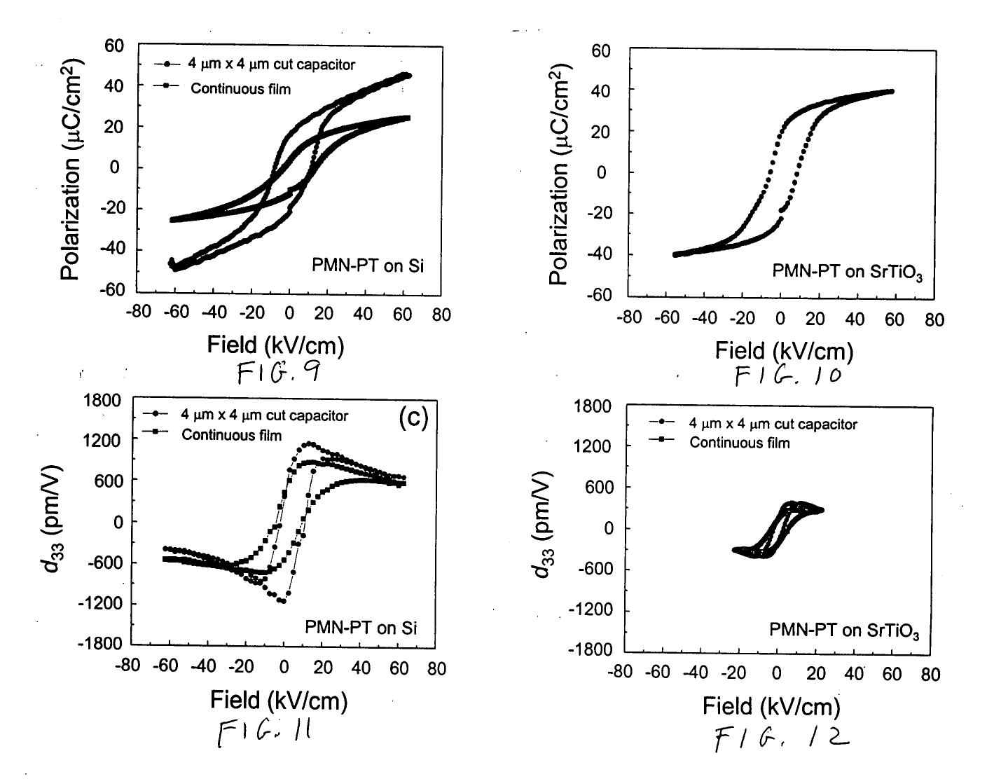

The piezoelectric and ferroelectric measurements of the 3.5 μm thick films, on both Si and SrTiO₃, are shown in FIGS. 9-12. The polarization-electric field (P-E) hysteresis loops were measured using a Radiant Technologies RT 6000 tester and an Aixacct TF2000 analyzer. FIG. 9 plots the P-E loop measured for the film on vicinal Si, while FIG. 10 is a plot of the P-E hysteresis loop for a film on SrTiO₃. We observe that the P-E loops for continuous films on SrTiO₃-buffered vicinal Si (2Pr from 5 to 8 μC/cm²), are strongly tilted and are not saturated. This can be understood as a consequence of the biaxial tensile strain imposed by the Si substrate as evident from the X-ray data, and is consistent with previous reports of low remanent polarizations in random and oriented PMN-PT films on Si. In contrast, films on SrTiO₃ show much squarer behavior with remanent polarizations of ˜22 μC/cm² (again consistent with the effect of biaxial compressive strain). In direct measurements of the properties of PMN-PT films on LaNiO₃/Si, it has been shown that when a biaxial tensile stress is applied via flexure of the substrate, the hysteresis loop rotated clockwise, resulting in lower remanent polarizations. Compressive stress resulted in a counterclockwise rotation, increasing the measured remanent polarization. See Z. Zhang, et al., “Oriented LaNiO₃ Bottom Electrodes and (001)-Textured Ferroelectric Thin Films on LaNiO₃,” MRS Proc. Ferroelectric Thin Films VIII, Vol. 596, 2000, pp. 73-77. The changes are often large enough to suggest that it may be possible to induce the tetragonal phase (with the polarization in the plane) in films under large tensile stresses. Interestingly, when the film on Si is laterally subdivided by FIB, the hysteresis loop recovers to a shape comparable to that of the epitaxial film on SrTiO₃ (Pᵣ 25-30 μC/cm²). This can be understood as a consequence of the removal of the biaxial strain constraint on the film which alters the electromechanical boundary conditions and hence the ferroelectric behavior.

Further evidence of this is observed in the piezoelectric measurements. The experimental procedure and quantitative measurements of the piezoelectric coefficients are described in C. S. Ganpule, et al., “Scaling of Ferroelectric and Piezoelectric Properties in Pt/SrBi₂Ta₂O₉/Pt thin films,” Appl. Phys. Lett., Vol. 75, 1999, pp. 3874-3876. FIG. 11 shows the longitudinal (d_{33,f}) piezoelectric coefficients for a continuous (clamped) 50 μm-diameter capacitor and a milled 4 μm×4 μm island for the film on SrTiO₃-buffered vicinal Si measured by piezoresponse microscopy. For the 50 μm capacitor, the maximum d₃₃ is approximately 800 pm/V. When measured after milling, the d_{33,f} increases to 1200 pm/V under a dc bias. This is far higher than values reported to date for PMN-PT films, and is consistent with the release of the lateral constraints on the film. Furthermore, the cut capacitors exhibit a stronger dependence on the applied field compared to the continuous capacitor, similar to previous results on soft PZT compositions. For the film on SrTiO₃, FIB milling increases the d₃₃ from 400 pm/V to 600 pm/V. This large difference in the piezoelectric responses between the islands on Si and SrTiO₃ might be due either to a change in the degree of clamping imposed by the substrate, or to differences in the residual stress values.

### Example 2

### Fabrication of a PZT-Based Piezoelectric Thin Film Structure

High quality epitaxial PZT thick films up to 4 μm were fabricated on both (001) SrTiO₃ and 4 degree miscut (001) Si substrates. Epitaxial (001) PZT films with various thicknesses (0.4-41 μm) were grown on (001) SrTiO₃ and 4 degree miscut (001) Si substrates using on-axis radio-frequency (RF) magnetron sputtering. The nominal composition of the sputtering target was PZT (Zr/Ti=52/48). Molecular-Beam-Epitaxy (MBE) was used to fabricate 100 Å of epitaxial (001) SrTiO₃ on the Si substrate as a seed layer in order to grow epitaxial PZT films. MBE methods of growing SrTiO₃ layers are described in, G. Y. Yang, J. M. Finder, J. Wang, Z. L. Wang, Z. Yu, J. Ramdani, R. Droopad, K. W. Eisenbeiser, and R. Ramesh, J. Mater. Res. 17, 204 (2002), the entire disclosure of which is incorporated herein by reference. Prior to the PZT film deposition, an epitaxial SrRuO₃ bottom electrode was deposited by 90° off-axis RF magnetron sputtering. RF magnetron sputtering techniques are described in, C. B. Eom, R. J. Cava, R. M. Fleming, J. M. Phillips, R. B. Vandover, J. H. Marshall, J. W. P. Hsu, J. J. Krajewski, and W. F. Peck, Science 258, 1766 (1992), the entire disclosure of which is incorporated herein by reference. During the PZT film deposition the substrate temperature was maintained at 600° C. with an oxygen pressure of 400 mTorr.

Epitaxial arrangement and three-dimensional strain states of the PZT films as a function of thickness were determined using a four-circle x-ray diffractometer (XRD). The crystalline quality of the PZT films was determined from the rocking curve widths of the PZT 002 reflections. With increasing film thickness for both substrates, the full width at half maximum (FWHM) of the rocking curve increased. The measured FWHM of the rocking curve, for the 3.8 μm thick PZT films on SrTiO₃, and Si was ˜0.57° and ˜0.67°, respectively. It was clear from the azimuthal φ-scan of the PZT 101 reflection that in-plane texture is cube-on-cube epitaxy without misoriented grains. Similar cube-on-cube epitaxy was also observed in case of PZT films on (001) SrTiO₃ substrates.

XRD way also used to show the variation of in-plane and out-of-plane lattice parameters of PZT films on Si and SrTiO₃ substrates as a function of film thickness. The out-of-plane lattice parameters were determined by normal θ-2θ scans. The in-plane lattice parameters were determined by off-axis reflections. It was found that the out-of-plane lattice parameter decreased and in-plane lattice parameter increased with film thickness, irrespective of the substrate.

Piezoelectric measurements were carried out using a piezoresponse force microscope (PFM). Methods of taking piezoelectric measurements using a PFM are described in V. Nagarajan, A. Stanishevsky, L. Chen, T. Zhao, B. T. Liu, J. Melngailis, A. L. Roytburd, R. Ramesh, J. Finder, Z. Yu, R. Droopad, and K. Eisenbeiser, Appl. Phys. Lett. 81, 4215 (2002), the entire disclosure of which is incorporated herein by reference. In general, the longitudinal piezoelectric coefficient (d₃₃) of thin or thick films are often influenced by the composition, orientation, and presence of non 180° domains. By fabricating ideal epitaxial films on suitable substrates, it could be possible to modify the domain orientations of PZT, and also their piezo-response. The results of the PFM studies showed the typical field dependent d₃₃ characteristics of 4 μm PZT on SrTiO₃ and Si substrates. It was clear that the films on Si have much higher value of d₃₃ (˜330 pm/V) than the films on SrTiO₃ (−200 pm/V). This result can be correlated to the pseudo-rhombohedral characteristics of PZT, as observed from structural data. The studies also showed the piezoelectric coefficients of the PZT films on SrTiO₃ and Si substrates as a function of film thickness. The nature of the increment of the d₃₃ value with film thickness was similar for the PZT films on both the substrates, however, the films on Si has significant enhancement of d₃₃. The increased piezoelectric coefficient with film thickness could be due to the reduction of substrate constraints and softening of the material by structural modification from higher tetragonal to lower tetragonal symmetry. This behavior could be directly correlated to the microstructure of the films on both the substrates. From the surface morphology by SEM microcracks were observed at the thickness above 2 μm for PZT films on Si substrates. There were no cracks found on PZT films on SrTiO₃ substrates. The cracks on thick (>2 μm) PZT films on Si substrates may be considered analogous to PZT cut-capacitors or islands of various sizes. However, the aspect ratio of those small capacitors is much higher than the observed cracks on PZT films on Si. Cracks were observed on PZT films at a separation 60 μm. It is likely that the continuous films have some substrate induced constraint and that pattering into small capacitors (1 μm×1 μm) could further improve the d₃₃ value. These thick epitaxial PZT films on Si with their high piezoelectric coefficients are well-suited for the fabrication of high performance electromechanical systems for high frequency applications.

### Example 3

### Fabrication of a BiFeO₃-Based Piezoelectric Thin Film Structure

A four layer structure including a 4 degree miscut Si substrate, a SrTiO₃ seed layer, a first overlayer composed of SrRuO₃ (100 nm thick) and a second overlayer composed of BiFeO₃ was fabricated. The SrTiO₃ seed layer and the SrRuO₃ overlayer were grown on the Si substrate using the same methods described in Example 1, above. A 600 nm thick BiFeO₃ film was then deposited by on-axis RF-magnetron sputtering from a stoichiometric sintered target. During BiFeO₃ film deposition, the substrate temperature is maintained at 690° C. with argon and oxygen partial pressures of 240 mTorr and 160 mTorr, respectively.

It is understood that the invention is not confined to the particular embodiments set forth herein as illustrative, but embraces all such forms thereof as come within the scope of the following claims.

What is claimed is:

1. A perovskite-based thin film structure comprising:
(a) a substrate layer of crystalline silicon having a top surface cut at an angle to the (001) crystal plane of the crystalline silicon, the angle of cut being between 1° and 20°;
(b) a perovskite seed layer epitaxially grown on the top surface of the substrate layer; and
(c) a perovskite overlayer epitaxially grown above the seed layer.

2. The thin film structure of claim 1 wherein the perovskite overlayer is grown to a thickness of at least 0.5 μm and has a substantially pure perovskite crystal structure.

3. The thin film structure of claim 2 wherein the perovskite overlayer has a thickness of at least 1 μm.

4. The thin film structure of claim 1 wherein the angle of cut of the substrate layer top surface is from 1° to 20° toward the (110) crystal plane of the crystalline substrate layer.

5. The thin film structure of claim 1 wherein the angle of cut of the substrate layer top surface is from 3° to 5° toward the (110) crystal plane of the crystalline substrate layer.

6. The thin film structure of claim 1 wherein the silicon substrate top surface is cut at an angle of about 4° to the (001) plane of the crystalline substrate toward the (110) plane.

7. The thin film structure of claim 1 wherein the perovskite overlayer is between 1 μm and 4 μm thick.

8. The thin film structure of claim 1 wherein the perovskite overlayer comprises a piezoelectric perovskite.

9. The thin film structure of claim 8 wherein the piezoelectric perovskite comprises PMN-PT.

10. The thin film structure of claim 9 wherein the PMN-PT is substantially free of pyrochlore phase.

11. The thin film structure of claim 9 wherein the PMN-PT has the composition Pb(Mg_{1/3}Nb_{2/3})O₃)_{0.67}(PbTiO₃)_{0.33}.

12. The thin film structure of claim 8 wherein the piezoelectric perovskite comprises PZT.

13. The thin film structure of claim 8 wherein the piezoelectric perovskite comprises PZN-PT.

14. The thin film structure of claim 1 wherein the perovskite overlayer comprises a magnetic perovskite.

15. The thin film structure of claim 14 wherein the magnetic perovskite comprises SrRuO₃.

16. The thin film structure of claim 1 wherein the perovskite overlayer comprises a multiferroic perovskite.

17. The thin film structure of claim 16 wherein the multiferroic perovskite comprises BiFeO₃.

18. The thin film structure of claim 1 wherein the perovskite seed layer is material selected from the group consisting of SrTiO₃, doped SrTiO₃, and SrRuO₃.

19. The thin film structure of claim 1 wherein the perovskite seed layer is formed of SrTiO₃.

20. The thin film structure of claim 9 wherein the perovskite seed layer is formed of SrTiO₃.

21. The thin film structure of claim 12 wherein the perovskite seed layer is formed of SrTiO₃.

22. The thin film structure of claim 15 wherein the perovskite seed layer is formed of SrTiO₃.

23. The thin film structure of claim 1 wherein the perovskite overlayer provides a second perovskite overlayer, the structure further providing a first perovskite overlayer epitaxially grown on the perovskite seed layer and underlying the second perovskite overlayer.

24. A perovskite-based thin film structure comprising:
(a) a substrate layer of crystalline silicon having a top surface cut at an angle to the (001) crystal plane, the angle of cut being between 1° and 20°;
(b) a SrTiO₃ seed layer epitaxially grown on the top surface of the substrate layer; and
(c) an SrRuO₃ layer epitaxially grown on the SrTiO₃ seed layer.

25. The thin film structure of claim 24, further comprising a PMN-PT layer epitaxially grown on the SrRuO₃ layer.

26. The thin film structure of claim 24, further comprising a PZT layer epitaxially grown on the SrRuO₃ layer.

27. The thin film structure of claim 24, further comprising a BiFeO₃ layer epitaxially grown on the SrRuO₃ layer.

28. A method for making a perovskite-based thin film structure, the method comprising:
(a) cutting a top surface of a crystalline silicon substrate at an angle to the (001) crystal plane, the angle of cut being between 1° and 20°;
(b) epitaxially growing a perovskite seed layer on the top surface of the substrate; and
(c) epitaxially growing a perovskite overlayer above the seed layer.

29. The method of claim 28 wherein the perovskite overlayer is grown to a thickness of at least 0.5 μm and has a substantially pure perovskite crystal structure.

30. The method of claim 28 wherein the angle of cut is from 3° to 5°.

31. The method of claim 28 wherein the perovskite seed layer comprises SrTiO₃ and the perovskite overlayer comprises a perovskite selected from the group consisting of PMN-PT, PZT and BiFeO₃.

32. The method of claim 31, further comprising epitaxially growing a perovskite electrode layer on the seed layer prior to growing the perovskite overlayer.

33. The method of claim 32 wherein the perovskite electrode layer comprises SrRuO₃.
